(19) United States
(12) Patent Application Publication
(10) Pub. No.: US 2022/0197806 A1
(43) Pub. Date: Jun. 23, 2022

(54) HIGH SPEED MEMORY SYSTEM INTEGRATION

(71) Applicant: Intel Corporation, Santa Clara, CA (US)

(72) Inventors: Shigeki TOMISHIMA, Portland, OR (US); Satish DAMARAJU, El Dorado Hills, CA (US); Altug KOKER, El Dorado Hills, CA (US)

(21) Appl. No.: 17/133,603

(22) Filed: Dec. 23, 2020

(51) Int. Cl. G06F 12/0844

(52) U.S. Cl. CPC G06F 12/0844; G06F 2212/651

(57) ABSTRACT

Embodiments disclosed herein include memory architectures with stacked memory dies. In an embodiment, an electronic device comprises a base die and an array of memory dies over and electrically coupled to the base die. In an embodiment, the array of memory dies comprise caches. In an embodiment, a compute die is over and electrically coupled to the array of memory dies. In an embodiment, the compute die comprises a plurality of execution units.

### TECHNICAL FIELD

Embodiments of the present disclosure relate to semiconductor devices, and more particularly to electronic packages with a compute die over an array of memory die stacks.

### BACKGROUND

The drive towards increased computing performance has yielded many different packaging solutions. In one such packaging solution, dies are arranged over a base substrate. The dies may include compute dies and memory dies. Connections between the compute dies and the memory dies are provided in the base substrate. While higher density is provided, the lateral connections over the base substrate result in higher power consumption and reduced bandwidth. Such integration may not be sufficient to meet the memory capacity and bandwidth needs of certain applications, such as high performance computing (HPC) applications.

### BRIEF DESCRIPTION OF THE DRAWINGS

FIG. 1A is a plan view illustration of an electronic package.

FIG. 1B is a cross-sectional illustration of the electronic package in FIG. 1A.

FIG. 1C is a schematic of a memory architecture for use with the electronic package in FIGS. 1A and 1B.

FIG. 2 is a perspective view illustration of a portion of an electronic package, in accordance with an embodiment.

FIG. 3 is a cross-sectional illustration of an electronic package, in accordance with an embodiment.

FIG. 4A is a schematic of a memory architecture for use with the electronic package in FIG. 3, in accordance with an embodiment.

FIG. 4B is a schematic of a memory architecture for use with the electronic package in FIG. 3, in accordance with an additional embodiment.

FIG. 4C is a schematic of a memory architecture for use with the electronic package in FIG. 3, in accordance with an additional embodiment.

FIG. 5A is a cross-sectional illustration of a memory die stack with substantially uniform dies in the stack, in accordance with an embodiment.

FIG. 5B is a cross-sectional illustration of a memory die stack with a single die that comprises a plurality of cache levels, in accordance with an embodiment.

FIG. 5C is a cross-sectional illustration of a memory die stack with individual dies that have different cache levels, in accordance with an embodiment.

FIG. 6 is a cross-sectional illustration of an electronic system with an electronic package that comprises a first die over an array of die stacks, in accordance with an embodiment.

FIG. 7 is a schematic of a computing device built in accordance with an embodiment.

### EMBODIMENTS OF THE PRESENT DISCLOSURE

Described herein are electronic packages with a compute die over an array of memory die stacks, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

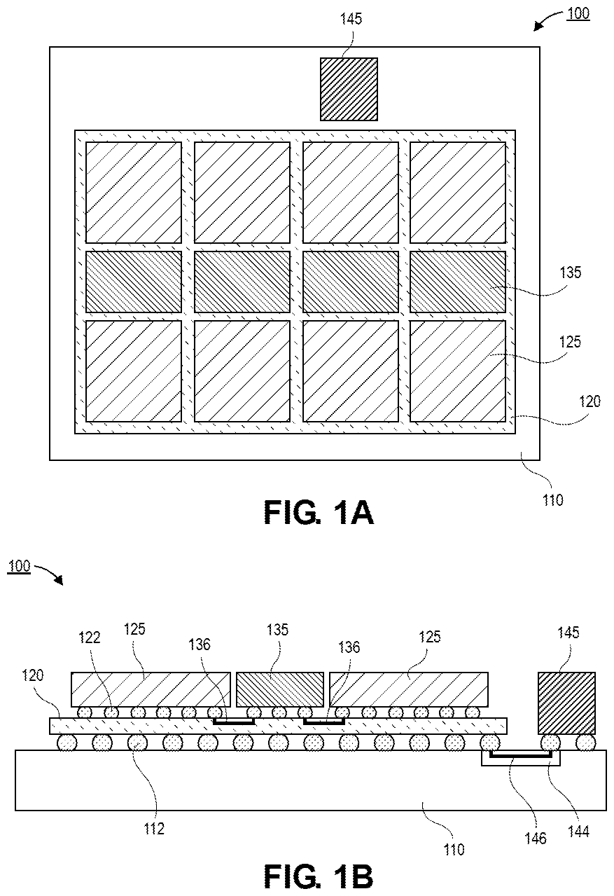

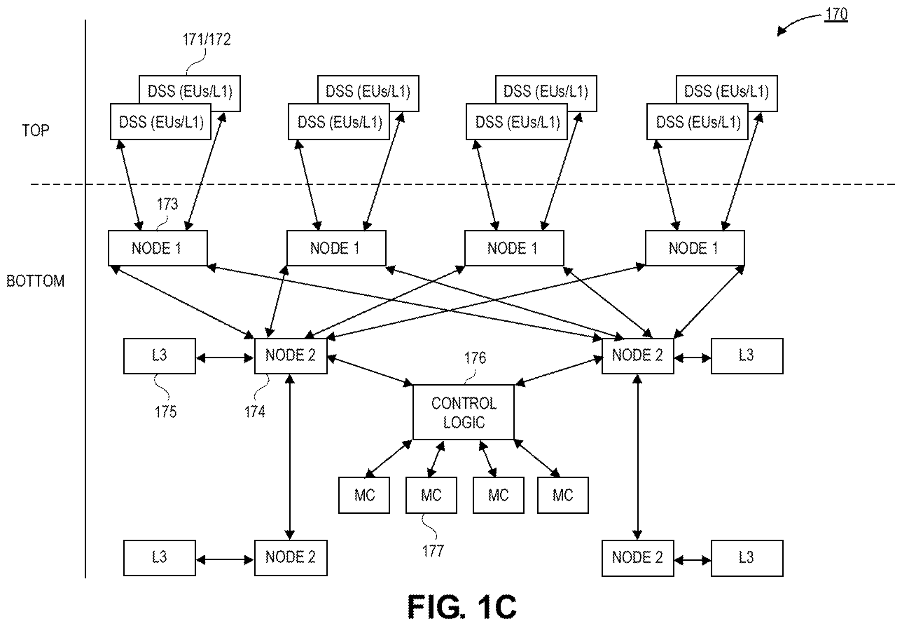

As noted above, existing electronic packaging architectures may not provide the memory capacity and bandwidth sufficient for some high performance computing (HPC) systems. An example of one such existing electronic package 100 is shown in FIGS. 1A and 1B. As shown, the electronic package 100 comprises a package substrate 110 with a base substrate 120 over the package substrate 110. The base substrate 120 may be an active substrate. For example, the base substrate 120 may comprise circuitry for memories (e.g., SRAM and other memory devices like eDRAM, MRAM, ReRAM, and others), I/O, and power management (e.g., a fully integrated voltage regulator (FIVR)). Integration of such circuitry components into the base substrate 120 requires a relatively advanced process node (e.g., 10 nm or smaller or larger). This is further complicated by the requirement that the area of the base substrate 120 be relatively larger (e.g., hundreds of mm²). As such, the yield of such base substrates 120 is low, which drives up the cost of the base substrate 120. The base substrate 120 may be attached to the package substrate 110 by interconnects 112.

As shown, a plurality of first dies 125 and second dies 135 may be disposed in an array over the base substrate 120. The first dies 125 may be compute dies (e.g., CPU, GPU, etc.), and the second dies 135 may be memory dies. The first dies 125 and the second dies 135 may be attached to the base substrate 120 by interconnects 122. It is to be appreciated that the number of second dies 135 is limited by the footprint of the base substrate 120. Since it is difficult to form large area base substrates 120, the number of second dies 135 is limited. As such, the memory capacity of the electronic package 100 is limited. In order to provide additional memory, a high bandwidth memory (HBM) 145 stack may be attached to the package substrate 110. The HBM 145 may be electrically coupled to the base substrate 120 by an embedded bridge 144 or other conductive routing architecture.

The first dies 125 may be electrically coupled to the second dies 135 through interconnects 136 (e.g., traces, vias, etc.) in the base substrate 120. Similarly, an interconnect 146 through the bridge 144 may electrically couple the HBM 145 to the base substrate 120. Such lateral routing increases power consumption and decreases the available bandwidth of the memory.

A memory architecture 170 used for the electronic package 100 is shown in FIG. 1C. As shown, the top layer (e.g., on the compute dies) comprises dual sub slice (DSS) execution units (EUs) 171 and level 1 (L1) caches 172, with each EUs 171 comprising a local L1 cache 172. As used herein, an EU may refer to transistors and the like on the compute die that are responsible for performing operations and calculations as instructed by a computer program. However, the remainder of the memory architecture 170 is implemented on the base substrate 120 (i.e., the bottom layer). The remainder of the memory architecture 170 may comprise first node logic units 173, second node logic units 174, level 3 (L3) caches 175, memory control logic 176, and memory controllers 177. The first node logic units 173 and the second node logic units 175 may be logic nodes used to route and/or retrieve information to/from the various memory caches (e.g., L3 caches 175). The logic nodes may comprise transistor devices and the like in order to implement the routing of data to the memory caches. The memory control logic 176 controls which memory controller 177 is accessed, and the memory controllers 177 provide data read/write capabilities. As such, the base substrate 120 comprises a relatively complex architecture that increases the complexity and cost of the base substrate.

In view of the limitations explained above in FIGS. 1A-1C, embodiments disclosed herein include an electronic packaging architecture that allows for improved memory capacity and bandwidth. Particularly, embodiments disclosed herein include a first die (e.g., a compute die) and an array of die stacks comprising second dies (e.g., memory dies) that are coupled to the first die. The three-dimensional (3D) stacking of the second dies allows for increased memory capacity within a restricted footprint. Additionally, each die stack may be located below a compute engine cluster of the first die. In some embodiments, local compute engines within a cluster may be above a memory block of individual ones of the second dies. Therefore, each compute engine cluster has direct access to memory with minimal lateral routing. This reduces the power consumption and provides an increase to bandwidth. In some embodiments, power delivery paths from a base substrate to the first die may be routed between the die stacks. In other embodiments, the power delivery paths may be routed through the die stacks. Particularly, it is to be appreciated that embodiments disclosed herein are not limited to any particular power delivery architecture.

The additional memory capacity also allows for offloading memory and complexity from the base substrate. Without the need to provide memory in the base substrate, the processing node of the base substrate may be relaxed. For example, the base substrate may be processed at the 14 nm or 22 nm or older process nodes. As such, yields of the base substrate are improved and costs are decreased. Additionally, larger area base substrates may be provided, which allows for even more memory capacity to be provided.

Furthermore, the addition of memory die stacks allows for increased flexibility in the memory architecture. Particularly, embodiments disclosed herein include off-loading some (or all) of the memory logic from the base substrate into the compute die and/or the stacked memory dies. The off-loading of components from the base die allows for decreased complexity, which may allow for a less advanced processing node to be used to fabricate the base die. This allows for larger base substrate footprints and/or improved base substrate yields. Increasing the base substrate footprint allows for more room for stacked memory dies, while improved yield decreases the cost of the base substrate.

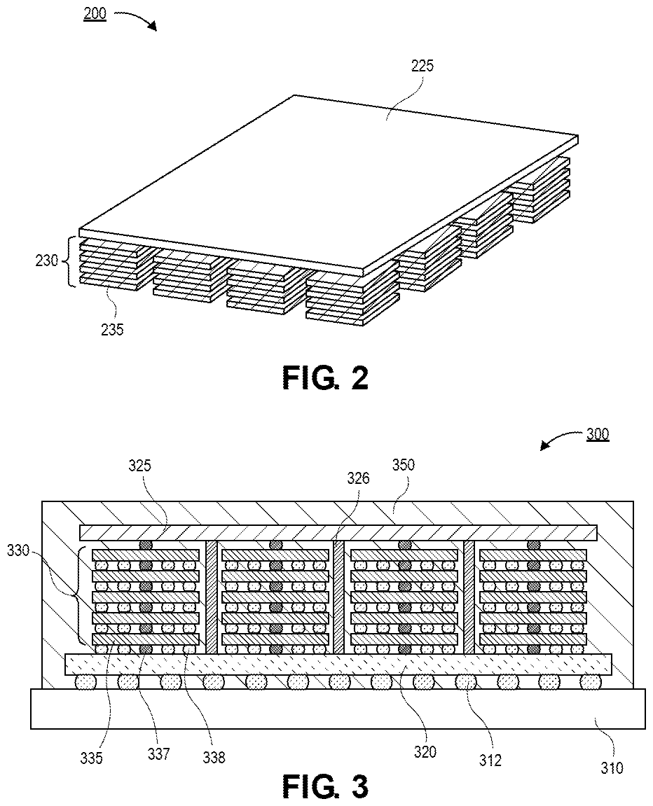

Referring now to FIG. 2 a perspective view illustration of a portion of an electronic package 200 is shown, in accordance with an embodiment. In FIG. 2, only the first die 225 and an array of die stacks 230 are shown for simplicity. It is to be appreciated that other components (as will be described in greater detail below) may be included in the electronic package 200. In an embodiment, the first die 225 may be a compute die. For example, the first die 225 may comprise a processor (e.g., CPU), a graphics processor (e.g. GPU), application processors (e.g., TPU, FPGA, etc.), or any other type of die that provides computation capabilities. In an embodiment, the die stacks 230 may comprise a plurality of second dies 235 arranged in a vertical stack. The second dies 235 may be memory dies. In a particular embodiment, the memory dies are SRAM memory, though other types of memory (e.g., eDRAM, STT-MRAM, ReRAM, 3DXP, etc.) may also be included in the die stacks 230. Additionally, the second dies 235 may comprise multiple different types of memories.

In the illustrated embodiment, the array of die stacks 230 comprises a four-by-four array. That is, there are 16 instances of the die stacks 230 shown in FIG. 2. However, it is to be appreciated that the array may comprise any number of die stacks 230. Furthermore, while a square array is shown, it is to be appreciated that the array may be any shape. For example, the array of die stacks 230 may be a four-by-two array. In the illustrated embodiment, each die stack 230 comprises four second dies 235. However, it is to be appreciated that embodiments may include any number of second dies 235 in the die stack 230. For example, one or more second dies 235 may be included in each die stack 230.

Referring now to FIG. 3, a cross-sectional illustration of an electronic package 300 is shown, in accordance with an embodiment. The electronic package 300 may comprise a package substrate 310, a base substrate 320, an array of die stacks 330, and a first die 325. A mold layer 350 may be disposed over the array of die stacks 330, the base substrate 320, and the first die 325.

In an embodiment, the package substrate 310 may be any suitable packaging substrate. For example, the package substrate 310 may be cored or coreless. In an embodiment, the package substrate 310 may comprise conductive features (not shown for simplicity) to provide routing. For example, conductive traces, vias pads, etc. may be included in the package substrate.

In an embodiment, each die stack 330 may comprise a plurality of second dies 335. In the illustrated embodiment five second dies 335 are shown in each die stack 330, but it is to be appreciated that the die stacks 330 may comprise one or more second dies 335. In an embodiment, the second dies 335 may be connected to each other by interconnects 337/338. Interconnects 338 represent power supply interconnects, and interconnects 337 may represent communication interconnects (e.g., I/O, CA, etc.). In an embodiment, through substrate vias (TSVs) may pass through the second dies 335. The TSVs are not shown for simplicity. In a particular embodiment, the interconnects 337/338 are implemented using a TSV/micro-bump architecture. In other embodiments, hybrid wafer bonding may be used to interconnect the stacked second dies. However, it is to be appreciated that other suitable interconnect architectures may also be used.

In an embodiment, the first die 325 may be a compute die. For example, the first die 325 may comprise a processor (e.g., CPU), a graphics processor (e.g. GPU), or any other type of die that provides computation capabilities. The second dies 335 may be memory dies. In a particular embodiment, the memory dies are SRAM memory, though other types of memory (e.g., e.g., eDRAM, STT-MRAM, ReRAM, 3DXP, etc.) may also be included in the die stacks 330. In an embodiment, the first die 325 may be fabricated at a different process node than the second dies 335. For example, the first die 325 may be fabricated with a more advanced process node than the second dies 335.

In an embodiment, the die stacks 330 that are integrated into the electronic package 300 may be known good die stacks 330. That is, the individual die stacks 330 may be tested prior to assembly. As such, embodiments may include providing only functional die stacks 330 in the assembly of the electronic package 300. This provides an increase in the yield of the electronic package 300 and reduces costs.

In an embodiment, a base substrate 320 is provided between the array of die stacks 330 and the package substrate 310. In an embodiment, the base substrate 320 may be attached to the package substrate 310 by interconnects 312, such as solder bumps or the like. The base substrate 320 may be a semiconductor material. For example, the base substrate 320 may comprise silicon or the like. In an embodiment, the base substrate 320 may be an active substrate that comprises active circuitry. In an embodiment, the base substrate 320 may comprise power regulation circuitry blocks (e.g., FIVR, or the like). In an embodiment, the base substrate 320 may also comprise portions of the memory architecture and/or additional memory caches, such as level 4 (L4) caches.

In some embodiments, the base substrate 320 may be fabricated at a process node that is different than the process nodes of the first die 325 and the second dies 335 in the die stacks 330. For example, the first die 325 may be fabricated at a 7 nm process node, the second dies 335 may be fabricated at a 10 nm process node, and the base substrate 320 may be fabricated at a 14 nm process node or larger. As such, the cost of the base substrate 320 is reduced. Additionally, the footprint of the base substrate 320 may be increased in order to provide more area for die stacks 330. In an embodiment, the footprint of the base substrate 320 may be larger than the footprint of the array of die stacks 330 and larger than the footprint of the first die 325. In an embodiment, the footprint of the base substrate 320 may be approximately 100 mm² or larger, approximately 200 mm² or larger, or approximately 500 mm² or larger.

In an embodiment, a power delivery path 326 from the base substrate 320 to the first die 325 may pass outside of the die stacks 330. As shown, power delivery paths 326 are positioned between the die stacks 330. In an embodiment, the power delivery paths 326 may comprise through mold vias (TMVs), copper pillars, or any other suitable interconnect architecture for providing a vertical connection through the mold layer 350.

Since the power delivery path to the first die 325 is not provided through the die stacks 330, the topmost second dies 335 may only include communication interconnects 337. However, in other embodiments, dummy power interconnects (i.e., interconnects that provide structural support but are not active parts of the circuitry) may be provided over the topmost second dies 335 to provide manufacturing and mechanical reliability. It is to be appreciated that the power delivery paths through the die stacks 330 may be made with interconnects 338.

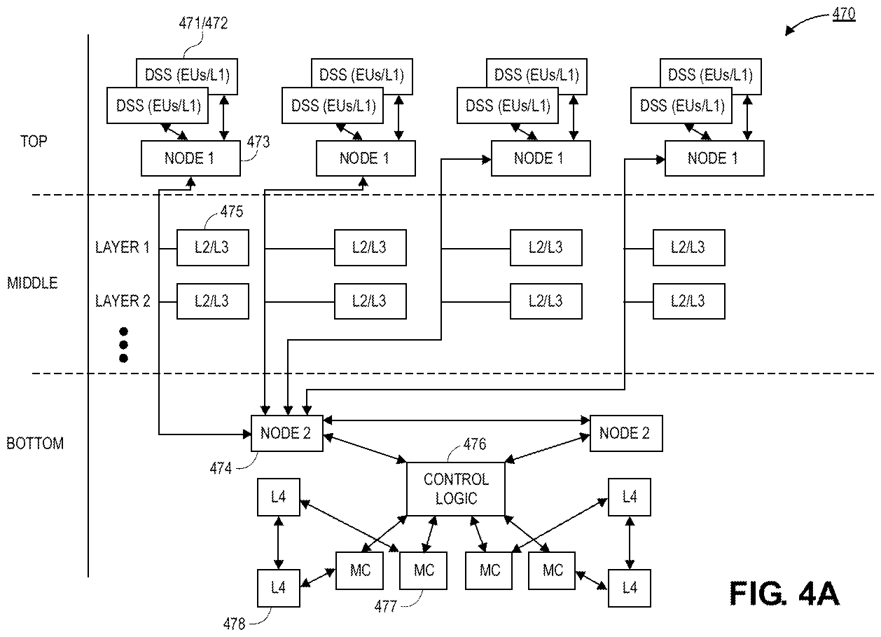

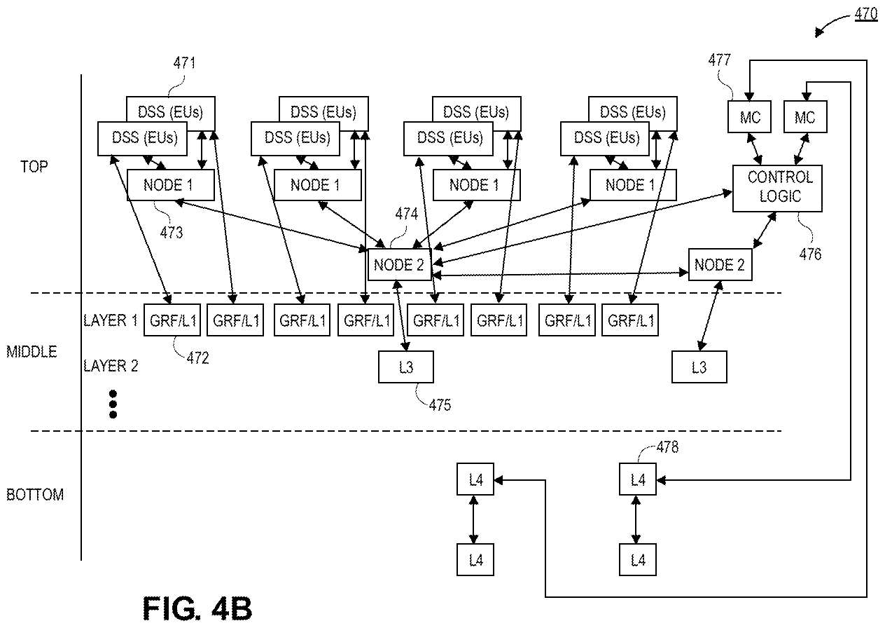

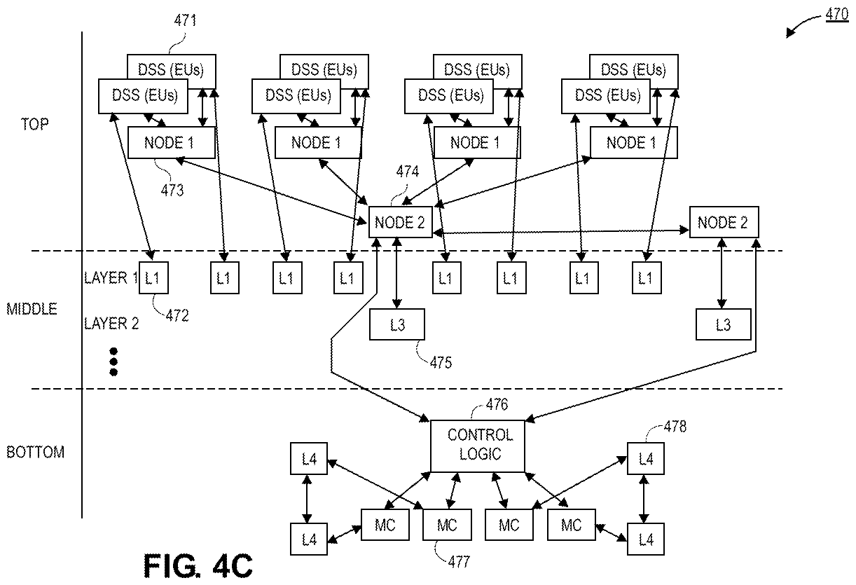

Referring now to FIG. 4A, a schematic illustration of the memory architecture 470 for an electronic package similar to electronic package 300 above is shown, in accordance with an embodiment. As shown, the memory architecture 470 is segmented into a top region, a middle region, and a bottom region. The top region corresponds with the compute die 325, the middle region corresponds with the second dies 335 in the die stacks 330 (that is, each layer in the middle region is a different second die 335 in the stack 330), and the bottom region corresponds with the base substrate 320.

In an embodiment, the top region includes the EUs 471 and the L1 cache 472. Each EUs 471 may be paired with an individual L1 cache 472. The L1 cache 472 is proximate to the EUs 471 and are shown in the same box. The L1 caches 472 may sometimes be referred to as local caches, since each L1 cache 472 is accessed by only a single EUs 471. In an embodiment, two or more EUs 471 and L1 cache 472 pairs may each be connected to a first node logic unit 473. The first node logic unit 473 may include logic for routing information between the EUs 471/ L1 cache 472 pairs that are coupled to the first node logic unit 473. As illustrated, the first node logic units 473 may be implemented in the top region on the compute die 325. This is different than existing architectures described above where the first node 173 is implemented in the base substrate 120 in the bottom region. As such, logic components may be offloaded from the base substrate 320 in accordance with embodiments disclosed herein.

In an embodiment, the middle region may comprise a plurality of L2/L3 caches 475. Each L2/L3 cache 475 may be implemented on a memory die 335 in a stack 330. Each layer (e.g., Layer 1, Layer 2, etc.) represents one layer in the stack 330. In the illustrated embodiment, a plurality of layers are shown. However, it is to be appreciated that in some embodiments, a single layer (Layer 1) may be provided. In an embodiment, the L2/L3 caches 475 are coupled between a first node logic unit 473 and a second node logic unit 474. Each of the L2/L3 caches 475 within a single stack 330 may be coupled between the same first node logic unit 473 and the same second node logic unit 474. The L2/L3 caches 475 may sometimes be referred to as shared caches. This is because each stack of L2/L3 caches 475 may be shared by more than one EUs 471 via the first node logic unit 473.

In an embodiment, the bottom region (i.e., the base substrate 320) may comprise the second node logic units 474 and memory control logic 476. The second node logic units 474 may be considered a global connection node. This is because each of the second node logic units 474 may be communicatively coupled to each other in order to access memory stored globally in the system. As shown, the second node logic unit 474 on the left is connected up to the illustrated first node logic units 473. While not shown for simplicity, the second node logic unit 474 on the right is similarly connected to first node logic units 473 that service additional EUs 471 (not shown).

In an embodiment, each of the second node logic units 474 are communicatively coupled to the memory control logic 476. The memory control logic 476 provides logic for determining which L4 cache 478 is accessed. Once a decision on which L4 cache 478 is to be accessed, a memory controller (MC) 477 for the selected L4 cache 478 provides operational logic to read, write, etc. onto the selected L4 cache 478. Each MC 477 may be communicatively coupled to a single one of the L4 caches 478. In some embodiments, the L4 caches 478 may also be communicatively coupled to one or more other L4 caches 478, as shown.

Referring now to FIG. 4B, a schematic illustration of a memory architecture 470 is shown, in accordance with an additional embodiment. The memory architecture 470 in FIG. 4B may be utilized in an electronic package similar to the electronic package 300 in FIG. 3. That is, a top region may correspond to the compute die 325, the middle region may correspond to the stack 330 of memory dies 335, and the bottom region may correspond to the base substrate 320.

In an embodiment, the top region may comprise a plurality of EUs 471. Each of the EUs may be communicatively coupled to a graphic resistor file (GRF)/L1 cache 472 in the middle region. While physically removed from the compute die 325, it is to be appreciated that the GRF/L1 caches 472 may be proximately located below the EUs 471 (e.g., in the first layer (Layer 1)) of the stack 330 in the middle region. Additionally, each of the GRF/L1 caches 472 service a single EUs 471, and may be referred to as a local cache in some embodiments.

In an embodiment, two or more EUs 471 may be communicatively coupled to a first node logic unit 473. The first node logic units 473 comprises logic for routing information between the EUs 471 that are coupled to the first node logic unit 473. As illustrated, the first node logic units 473 may be implemented in the top region on the compute die 325. This is different than existing architectures described above where the first node 173 is implemented in the base substrate 120 in the bottom region. As such, logic components may be offloaded from the base substrate in 320 in accordance with embodiments disclosed herein.

In an embodiment, each of the first node logic units 473 may be communicatively coupled to a second node logic unit 474. The second node logic unit 474 may be referred to as a global connection since each of the second node logic units 474 may be communicatively coupled to each other in order to access memory stored globally in the system. As shown, the second node logic unit 474 on the left is connected up to the illustrated first node logic units 473. While not shown for simplicity, the second node logic unit 474 on the right is similarly connected to first node logic units 473 that service additional EUs 471 (not shown).

In an embodiment, each of the second node logic units 474 may be communicatively coupled to an L3 cache 475. The L3 cache 475 may be provided in the middle region within the stack 330 of memory dies 335. In the embodiment illustrated in FIG. 4B, the L3 cache 475 may be provided in layer 2 of the stack 330 below the GRF/L1 caches 472. Though, it is to be appreciated that the L3 cache 475 may be provided in any of the layers of the stack 330. Due to the global connection of the second node logic units 474, information within the L3 caches 475 may be accessed by any of the EUs 471. Additionally, the illustrated embodiment is implemented without an L2 cache. However, it is to be appreciated that an L2 cache may optionally be included in the middle region within the stack 330 of memory dies 335 in some embodiments.

In the illustrated embodiment, the second node logic units 474 are provided in the top region on the compute die 325. As such, additional logic modules may be offloaded from the base substrate 320 in the bottom region of the architecture 470. This reduces the complexity of the base substrate 320 and allows for higher yields and/or larger base substrates 320.

In an embodiment, the second node logic units 474 may also be communicatively coupled to the memory control logic 476. The memory control logic 476 provides logic for determining which L4 cache 478 is accessed. Once a decision on which L4 cache 478 is to be accessed, an MC 477 for the selected L4 cache 478 provides operational logic to read, write, etc. onto the selected L4 cache 478. Each MC 477 may be communicatively coupled to a single one of the L4 caches 478. In some embodiments, the L4 caches 478 may also be communicatively coupled to one or more other L4 caches 478, as shown.

As shown in FIG. 4B, the memory control logic 476 and the MCs 477 may also be provided in the top region on the compute die 325. In an embodiment, the L4 caches 478 may remain in the bottom region on the base substrate 320. As such, additional logic modules may be offloaded from the base substrate 320 in the bottom region of the architecture 470. This reduces the complexity of the base substrate 320 and allows for higher yields and/or larger base substrates 320.

Referring now to FIG. 4C, a schematic illustration of a memory architecture 470 is shown, in accordance with an additional embodiment. The memory architecture 470 in FIG. 4C may be utilized in an electronic package similar to the electronic package 300 in FIG. 3. That is, a top region may correspond to the compute die 325, the middle region may correspond to the stack 330 of memory dies 335, and the bottom region may correspond to the base substrate 320.

In an embodiment, the top region may comprise a plurality of EUs 471. Each of the EUs 471 may be communicatively coupled to an L1 cache 472 in the middle region. While physically removed from the compute die 325, it is to be appreciated that the L1 caches 472 may be proximately located below the EUs 471 (e.g., in the first layer (Layer 1)) of the stack 330 in the middle region. Additionally, each of the L1 caches 472 service a single EUs 471, and may be referred to as a local cache in some embodiments.

In an embodiment, two or more EUs 471 may be communicatively coupled to a first node logic unit 473. The first node logic units 473 comprises logic for routing information between the EUs 471 that are coupled to the first node logic unit 473. As illustrated, the first node logic units 473 may be implemented in the top region on the compute die 325. This is different than existing architectures described above where the first node 173 is implemented in the base substrate 120 in the bottom region. As such, logic components may be offloaded from the base substrate in 320 in accordance with embodiments disclosed herein.

In an embodiment, each of the first node logic units 473 may be communicatively coupled to a second node logic unit 474. The second node logic unit 474 may be referred to as a global connection since each of the second node logic units 474 may be communicatively coupled to each other in order to access memory stored globally in the system. As shown, the second node logic unit 474 on the left is connected up to the illustrated first node logic units 473. While not shown for simplicity, the second node logic unit 474 on the right is similarly connected to first node logic units 473 that service additional EUs 471 (not shown).

In an embodiment, each of the second node logic units 474 may be communicatively coupled to an L3 cache 475. The L3 cache 475 may be provided in the middle region within the stack 330 of memory dies 335. In the embodiment illustrated in FIG. 4B, the L3 cache 475 may be provided in Layer 2 of the stack 330 below the L1 caches 472. Though, it is to be appreciated that the L3 cache 475 may be provided in any of the layers of the stack 330. Due to the global connection of the second node logic units 474, information within the L3 caches 475 may be accessed by any of the EUs 471. Additionally, the illustrated embodiment is implemented without an L2 cache. However, it is to be appreciated that an L2 cache may optionally be included in the middle region within the stack 330 of memory dies 335 in some embodiments.

In the illustrated embodiment, the second node logic units 474 are provided in the top region on the compute die 325. As such, additional logic modules may be offloaded from the base substrate 320 in the bottom region of the architecture 470. This reduces the complexity of the base substrate 320 and allows for higher yields and/or larger base substrates 320.

In an embodiment, the second node logic units 474 may also be communicatively coupled to the memory control logic 476. The memory control logic 476 provides logic for determining which L4 cache 478 is accessed. Once a decision on which L4 cache 478 is to be accessed, an MC 477 for the selected L4 cache 478 provides operational logic to read, write, etc. onto the selected L4 cache 478. Each MC 477 may be communicatively coupled to a single one of the L4 caches 478. In some embodiments, the L4 caches 478 may also be communicatively coupled to one or more other L4 caches 478, as shown.

In an embodiment, the memory control logic 476 and the MCs 477 may be provided in the bottom region on the base substrate 320. Therefore, the embodiment in FIG. 4C provides an intermediate solution between the embodiments in FIGS. 4A and 4B. The intermediate solution involves splitting the memory control logic 476 and the second node logic units 474 into different regions of the architecture 470. In contrast, in the embodiment of FIG. 4A, the second node logic units 474 and the memory control logic 476 are both in the base substrate 320, and in the embodiment of FIG. 4B, the second node logic units 474 and the memory control logic 476 are both in the compute die 325.

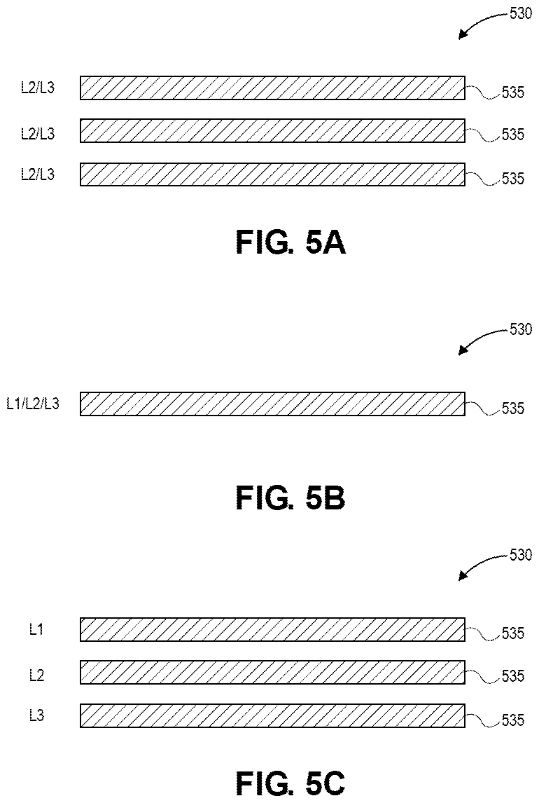

Referring now to FIGS. 5A-5C, cross-sectional illustrations of die stacks 530 are shown, in accordance with various embodiments. In FIG. 5A, the die stack 530 comprises a plurality of dies 535 that are all substantially the same. For example, the plurality of dies 535 may each comprise L2/L3 caches. Providing uniform dies 535 allows for easier integration and may result in a decrease in the cost of the die stack 530.

Referring now to FIG. 5B, a cross-sectional illustration of a die stack 530 with a single die 535 is shown, in accordance with an embodiment. As shown, the single die 535 may comprise a plurality of different caches. For example, the die 535 in FIG. 5B comprises L1 caches, L2 caches, and L3 caches. Such an embodiment may be particularly beneficial when the die stack 530 comprises only one die 535 that needs to accommodate different cache levels.

Referring now to FIG. 5C, a cross-sectional illustration of a die stack 530 with a plurality of dies 535 is shown, in accordance with an additional embodiment. As shown, each die 535 in the die stack 530 is configured to provide different cache levels. For example, the topmost die 535 provides L1 cache, the middle die 535 provides L2 cache, and the bottommost die 535 provides L3 cache.

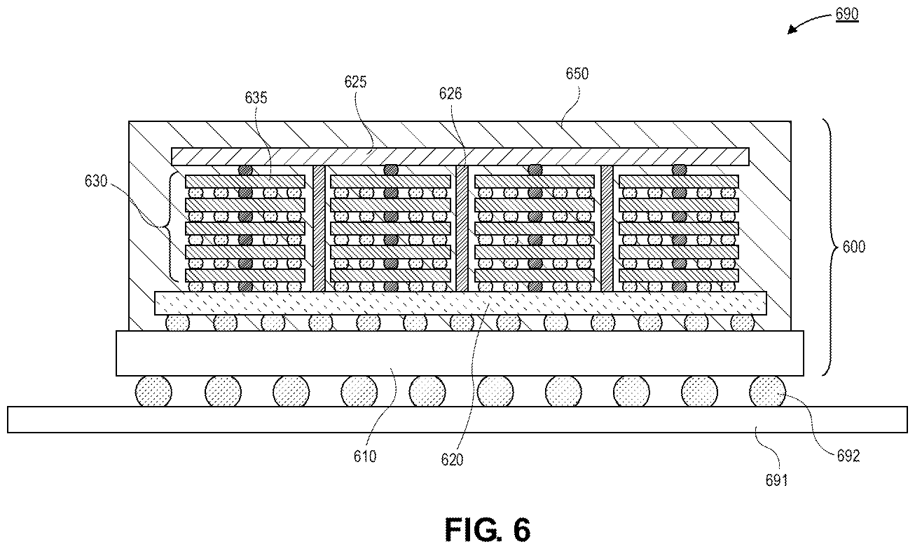

Referring now to FIG. 6, a cross-sectional illustration of an electronic system 690 is shown, in accordance with an embodiment. In an embodiment, the electronic system 690 may comprise an electronic package 600 that is attached to a board 691. The electronic package 600 may be attached to the board 691 by interconnects 692. In the illustrated embodiment, the interconnects 692 are shown as being solder balls. However, it is to be appreciated that the interconnects 692 may be any suitable interconnects, such as sockets, wire bonds, or the like. In an embodiment, electronic package 600 may be substantially similar to any of the electronic packages described herein, such as electronic package 300.

In an embodiment, the electronic package 600 may comprise a package substrate 610. A base substrate 620 may be disposed over the package substrate 610. In an embodiment, an array of die stacks 630 may be positioned over the base substrate 620. The die stacks 630 may each comprise a plurality of second dies 635. For example, the second dies 635 may be memory dies. A first die 625 may be disposed over the die stacks 630. The first die 625 may be a compute die. In an embodiment, the first die 625 may be provided power through a power delivery paths 626 that directly connects to the base substrate 620. In an embodiment, a mold layer 650 may surround the electronic package 600.

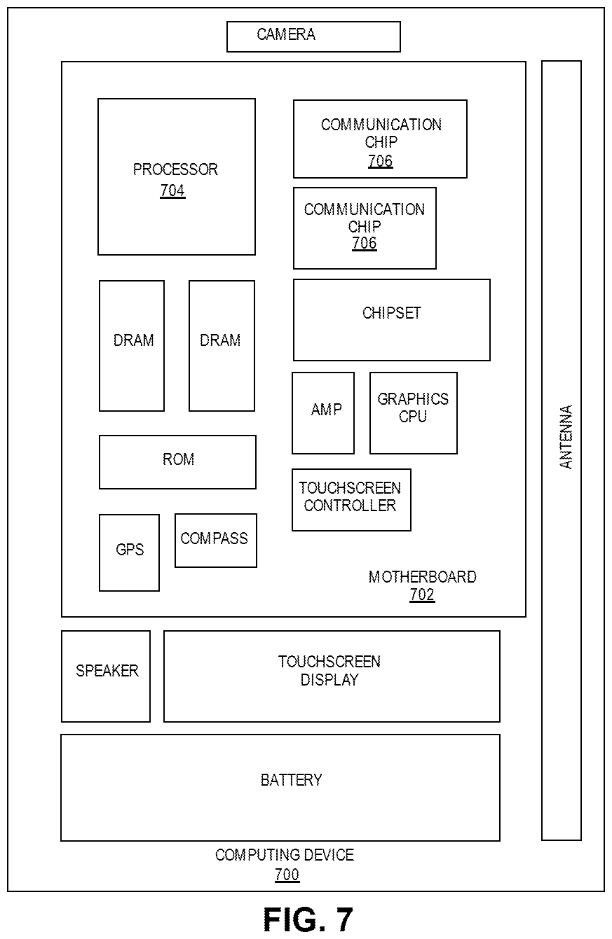

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package that comprises a first die over an array of die stacks, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package that comprises a first die over an array of die stacks, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic device, comprising: a base die; an array of memory dies over and electrically coupled to the base die wherein the array of memory dies comprise caches; and a compute die over and electrically coupled to the array of memory dies, wherein the compute die comprises a plurality of execution units.

Example 2: the electronic device of Example 1, wherein the compute die further comprises level 1 caches, and wherein the memory die comprises level 3 caches

Example 3: the electronic device of Example 2, wherein the compute die further comprises first node logic units.

Example 4: the electronic device of Example 3, wherein the base die comprises second node logic units and memory control logic

Example 5: the electronic device of Example 4, wherein the base die further comprises level 4 caches.

Example 6: the electronic device of Examples 1-5, wherein the compute die further comprises first node logic units and second node logic units.

Example 7: the electronic device of Example 6, wherein the array of memory dies further comprises level 1 caches.

Example 8: the electronic device of Example 6 or Example 7, wherein the compute die further comprises memory control logic.

Example 9: the electronic device of Examples 6-8, wherein the base die comprises memory control logic.

Example 10: the electronic device of Examples 1-9, wherein the array of memory dies comprises a plurality of memory die stacks.

Example 11: the electronic device of Example 10, wherein individual memory dies within a memory die stack all comprise the same cache levels.

Example 12: the electronic device of Example 10, wherein individual memory dies within a memory die stack comprise different cache levels.

Example 13: a memory architecture for a multi-chip package with a base die, an array of memory die stacks over the base die, and a compute die over the array of memory die stacks, the memory architecture comprising: execution units on the compute die; first node logic units on the compute die; and caches on the array of memory die stacks.

Example 14: the memory architecture of Example 13, further comprising: level 1 caches on the compute die, and wherein level 3 caches are on the array of memory die stacks.

Example 15: the memory architecture of Example 13, further comprising: level 1 caches on the array of memory die stacks.

Example 16: the memory architecture of Examples 13-15, further comprising: second node logic units on the compute die.

Example 17: the memory architecture of Example 16, further comprising: memory control logic on the compute die.

Example 18: the memory architecture of Example 16, further comprising: memory control logic on the base die.

Example 19: the memory architecture of Example 18, wherein the memory control logic is communicatively coupled to level 4 cache on the base die.

Example 20: the memory architecture of Examples 16-19, wherein individual ones of the second node logic units are communicatively coupled to a plurality of first node logic units.

Example 21: the memory architecture of Examples 13-20, wherein individual ones of the first node logic units are communicatively coupled to two or more execution units.

Example 22: the memory architecture of Examples 13-21, wherein individual memory dies within a memory die stack all comprise the same cache levels.

Example 23: the memory architecture of Examples 13-22, wherein individual memory dies within a memory die stack comprise different cache levels.

Example 24: an electronic system, comprising: a board; a package substrate attached to the board; a base die attached to the package substrate; an array of memory dies over and electrically coupled to the base die wherein the array of memory dies comprise caches; and a compute die over and electrically coupled to the array of memory dies, wherein the compute die comprises a plurality of execution units.

Example 25: the electronic system of Example 24, further comprising: a plurality of first nodes, wherein individual ones of the plurality of first nodes are communicatively coupled to two or more execution units, and wherein the plurality of first nodes are provided on the compute die.

What is claimed is:

1. An electronic device, comprising:
a base die;
an array of memory dies over and electrically coupled to the base die wherein the array of memory dies comprise caches; and
a compute die over and electrically coupled to the array of memory dies, wherein the compute die comprises a plurality of execution units.

2. The electronic device of claim 1, wherein the compute die further comprises level 1 caches, and wherein the memory die comprises level 3 caches.

3. The electronic device of claim 2, wherein the compute die further comprises first node logic units.

4. The electronic device of claim 3, wherein the base die comprises second node logic units and memory control logic.

5. The electronic device of claim 4, wherein the base die further comprises level 4 caches.

6. The electronic device of claim 1, wherein the compute die further comprises first node logic units and second node logic units.

7. The electronic device of claim 6, wherein the array of memory dies further comprises level 1 caches.

8. The electronic device of claim 6, wherein the compute die further comprises memory control logic.

9. The electronic device of claim 6, wherein the base die comprises memory control logic.

10. The electronic device of claim 1, wherein the array of memory dies comprises a plurality of memory die stacks.

11. The electronic device of claim 10, wherein individual memory dies within a memory die stack all comprise the same cache levels.

12. The electronic device of claim 10, wherein individual memory dies within a memory die stack comprise different cache levels.

13. A memory architecture for a multi-chip package with a base die, an array of memory die stacks over the base die, and a compute die over the array of memory die stacks, the memory architecture comprising:
execution units on the compute die;
first node logic units on the compute die; and
caches on the array of memory die stacks.

14. The memory architecture of claim 13, further comprising:
level 1 caches on the compute die, and wherein level 3 caches are on the array of memory die stacks.

15. The memory architecture of claim 13, further comprising:
level 1 caches on the array of memory die stacks.

16. The memory architecture of claim 13, further comprising:
second node logic units on the compute die.

17. The memory architecture of claim 16, further comprising:
memory control logic on the compute die.

18. The memory architecture of claim 16, further comprising:
memory control logic on the base die.

19. The memory architecture of claim 18, wherein the memory control logic is communicatively coupled to level 4 cache on the base die.

20. The memory architecture of claim 16, wherein individual ones of the second node logic units are communicatively coupled to a plurality of first node logic units.

21. The memory architecture of claim 13, wherein individual ones of the first node logic units are communicatively coupled to two or more execution units.

22. The memory architecture of claim 13, wherein individual memory dies within a memory die stack all comprise the same cache levels.

23. The memory architecture of claim 13, wherein individual memory dies within a memory die stack comprise different cache levels.

24. An electronic system, comprising:
a board;
a package substrate attached to the board;
a base die attached to the package substrate;
an array of memory dies over and electrically coupled to the base die wherein the array of memory dies comprise caches; and
a compute die over and electrically coupled to the array of memory dies, wherein the compute die comprises a plurality of execution units.

25. The electronic system of claim 24, further comprising:
a plurality of first nodes, wherein individual ones of the plurality of first nodes are communicatively coupled to two or more execution units, and wherein the plurality of first nodes are provided on the compute die.
